(19) United States
(12) Patent Application Publication
(10) Pub. No.: US 2026/0025989 A1
(43) Pub. Date: Jan. 22, 2026

(54) ANTI-FUSE DEVICES AND METHODS OF FORMING THE SAME

(71) Applicant: Adeia Semiconductor Bonding Technologies Inc., San Jose, CA (US)

(72) Inventors: Pawel Mrozek, San Jose, CA (US); Gaius Gillman Fountain, JR., Youngsville, NC (US); Cyprian Emeka Uzoh, San Jose, CA (US); Belgacem Haba, Saratoga, CA (US)

(21) Appl. No.: 18/978,469

(22) Filed: Dec. 12, 2024

Related U.S. Application Data
(60) Provisional application No. 63/673,471, filed on Jul. 19, 2024.

(51) Int. Cl. H10B 20/25

(52) U.S. Cl. CPC H10B 20/25

(57) ABSTRACT

A semiconductor device comprises selectively programmable anti-fuses. A method comprises forming a plurality of anti-fuses. Each anti-fuse comprises a copper oxide anti-fuse block that electrically separates at least two conductive copper features. The method further comprises selectively reducing the copper oxide of one or more of the anti-fuse blocks to form a conductive path between respective conductive features.

### CROSS REFERENCE TO RELATED APPLICATION

This application claims the benefit of U.S. Provisional Patent Application No. 63/673,471, filed Jul. 19, 2024, which is hereby incorporated by reference herein in its entirety.

### FIELD

The present disclosure relates to anti-fuses, semiconductor devices including anti-fuses, and methods of manufacturing the same.

### BACKGROUND

Manufacturing a semiconductor device (e.g., chip) may be expensive and the ability to repair or modify a semiconductor device after manufacturing can result in significant cost savings. However, typical semiconductor devices may have computer logic hard-wired into the device and cannot be changed after the semiconductor devices are manufactured. Accordingly, there is a need in the art for improved semiconductor devices and methods of manufacturing the same.

### SUMMARY

Embodiments herein provide for anti-fuses. Advantageously, the anti-fuses may enable repairing of damaged chips and/or chip stacks in addition to programming of chips and/or chip stacks after manufacturing is completed.

One general aspect includes a method of manufacturing a semiconductor device comprising selectively programmable anti-fuses. The method comprises forming a plurality of anti-fuses, each comprising a copper oxide anti-fuse block that electrically separates at least two conductive copper features and reducing the copper oxide of one or more copper oxide anti-fuse blocks to form a conductive path between respective conductive copper features.

The anti-fuse blocks may be formed in different ways. In some embodiments, the method of forming the copper oxide anti-fuse blocks comprises exposing the conductive copper features to an oxygen based plasma. In some embodiments, the method of forming the copper oxide anti-fuse blocks comprises thermally oxidizing exposed surfaces of the conductive copper features. In some embodiments, the method of forming the copper oxide anti-fuse blocks comprises physical vapor deposition of copper in the presence of oxygen. In some embodiments, the method of forming the copper oxide anti-fuse blocks comprises physical vapor deposition of copper oxide by reactive sputtering from a copper oxide target. In some embodiments, the method of forming the copper oxide anti-fuse blocks uses a successive ionic layer adsorption and reaction process. In some embodiments, the method of forming the copper oxide anti-fuse blocks uses an electrochemical oxidation process.

The copper oxide may be reduced in different ways. In some embodiments, reducing the copper oxide comprises heating and maintaining the semiconductor device at greater than about 150° C., and using a laser to selectively heat the one or more of the copper oxide anti-fuse blocks. In some embodiments, reducing the copper oxide comprises using a pulsed thermal anneal process. In some embodiments, the semiconductor device comprises resistors disposed proximate to the copper oxide anti-fuse blocks and reducing the copper oxide comprises heating the one or more copper oxide anti-fuse blocks by flowing a current through the resistors proximate thereto. In some embodiments, reducing the copper oxide further comprises locally heating the one or more copper oxide anti-fuse blocks by flowing a current through the copper to copper oxide junctions. In some embodiments, the copper oxide anti-fuse block and the conductive copper features are disposed in a first oxide layer, which has a higher hydrogen content than a surrounding second oxide layer, and reducing the copper oxide comprises reacting the copper oxide with hydrogen in the first oxide layer. The first oxide layer may be formed using silane (SiH₄). In some embodiments, reducing the copper oxide to copper comprises annealing in forming gas at about 200° C. to about 250° C. In some embodiments, reducing the copper oxide to copper comprises hydrogen gas plasma reduction of copper oxide. In some embodiments, reducing the copper oxide to copper comprises any combination of methods described above.

In some embodiments, the at least two conductive copper features comprise a first conductive feature and a second conductive feature. In some embodiments, the first conductive feature and the second conductive feature are disposed in a same substrate. In some embodiments, the first conductive feature is disposed in a first substrate and the second conductive feature is disposed in a second substrate.

In some embodiments, the method further comprises contacting the first substrate to the second substrate to form a workpiece and heating the workpiece to about 150° C. or more, wherein heating the workpiece reduces the copper oxide of the one or more copper oxide anti-fuse blocks.

Another general aspect includes a semiconductor device. Generally, the semiconductor device includes a plurality of anti-fuses, each comprising a copper oxide anti-fuse block that electrically separates at least two conductive copper features, and one or more copper oxide anti-fuse blocks is reduced to form a conductive path between respective conductive copper features.

In some embodiments, the copper oxide anti-fuse block and the at least two conductive copper features are disposed in a first oxide layer, and the first oxide layer has a higher hydrogen content than a surrounding second oxide layer. In some embodiments, resistors are disposed proximate to the copper oxide anti-fuse blocks.

In some embodiments, the semiconductor device further comprises a substrate. The at least two conductive copper features may comprise a first conductive feature and a second conductive feature. The first conductive feature and the second conductive feature may be disposed in the substrate.

In some embodiments, the semiconductor device further comprises a first substrate and a second substrate. The at least two conductive copper features may comprise a first conductive feature and a second conductive feature. The first conductive feature may be disposed in the first substrate, and the second conductive feature may be disposed in the second substrate. The first substrate may be directly bonded to the second substrate.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1D schematically illustrates views of example anti-fuses, according to some embodiments;

FIG. 2 shows an example method to reduce an anti-fuse, according to some embodiments;

FIGS. 3A-3B schematically illustrates cross-sectional views of an example anti-fuse, according to some embodiments;

FIGS. 4A-4C schematically illustrate example process flows of manufacturing example anti-fuses, according to some embodiments;

FIG. 5 schematically illustrates a cross-sectional view of an example anti-fuse, according to some embodiments;

FIG. 6 schematically illustrates cross-sectional views of an example anti-fuse and an arrangement for reducing an anti-fuse, according to some embodiments;

FIG. 7 schematically illustrates cross-sectional views of example anti-fuses and an example method to reduce an anti-fuse, according to some embodiments;

FIG. 8 schematically illustrates cross-sectional views of example anti-fuses and an example method to reduce an anti-fuse, according to some embodiments;

FIG. 9 schematically illustrates cross-sectional views of example anti-fuses and an example method to reduce an anti-fuse, according to some embodiments; and

FIGS. 10A-10B schematically illustrate hybrid bonding, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein provide for anti-fuses and methods of forming the same. The anti-fuses may be between conductive features of a chip or conductive features between multiple chips. Advantageously, the anti-fuses may enable programming of chips and/or chip stacks after manufacturing is completed

As described below, semiconductor substrates herein generally have a “device side,” e.g., the side on which semiconductor device elements are fabricated, such as transistors, resistors, capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

Manufacturing a chip may be expensive and the ability to save a chip by repairing or modifying it after manufacturing can result in significant cost savings. Computer logic may be generally etched or hard-wired onto a chip and cannot be changed after the chip has been manufactured. However, changes to circuits on a chip after manufacturing can be enabled by using fuses and anti-fuses. For example, in computing a fuse may be an electronic fuse (eFuse) or microscopic fuse in a computer chip. An anti-fuse is an electrical device that performs the opposite function of a fuse. Whereas a fuse may start with a low resistance path and may be designed to permanently break an electrically conductive path (e.g., when current through the path exceeds a specified limit), an anti-fuse may start with a high resistance path and programming it may convert it into a permanently electrically conductive path (e.g., when voltage exceeds a certain level).

Embodiments herein provide for anti-fuses (e.g., copper oxide anti-fuse), methods of forming the same, and methods to reduce anti-fuses (e.g., copper oxide of an anti-fuse to copper) to form a conductive path within or between substrates (e.g., integrated circuits ICs, chiplets, wafer to wafer, die to wafer, etc.).

Anti-fuses may be used in various applications for programming conductive paths in manufactured devices. For example, the anti-fuses can be used to fix defective paths post-manufacturing by programming redundant elements to replace defective elements. Anti-fuses may be used to customize circuits in pre-made chips. Anti-fuses may be used to unlock paths to enable or activate redundancy. Anti-fuses may be used for security programming, die programming, and/or integrated device identification. Anti-fuses may be used for programming or controlling the resistance and/or speed of a device. Anti-fuses can be used in various devices, including wafer to wafer (W2W) bonded structures, die to wafer (D2W) bonded structures, integrated circuits, chiplets, etc. The W2W and D2W bonded structures may include Direct Bonding Interconnect (DBI) structures. Devices may include bonded structures such as DBI on DBI, DBI on Through Silicon Via (TSV), and TSV on TSV.

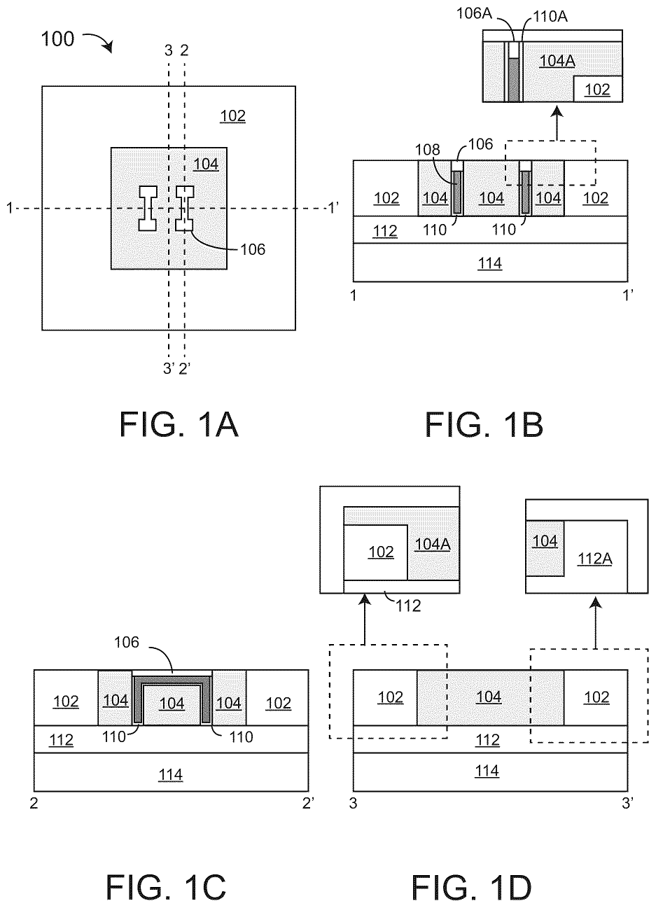

FIGS. 1A-1D schematically illustrates views of example anti-fuse device 100, according to some embodiments. Cross-sectional views as shown in FIGS. 1B-1D are schematic sectional views taken along lines 1-1′, 2-2′, and 3-3′, respectively, as shown on the top view in FIG. 1A.

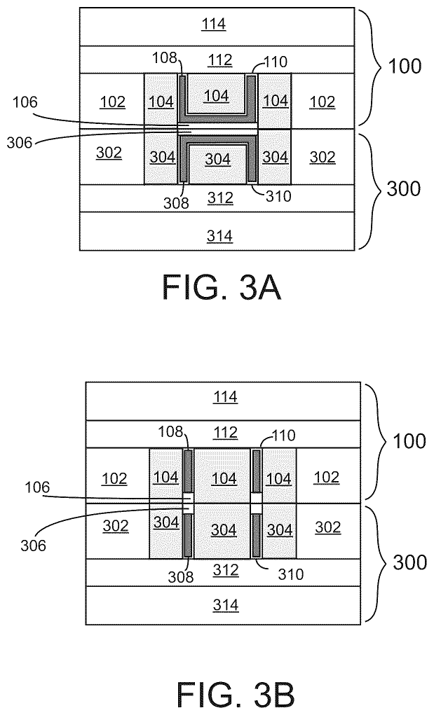

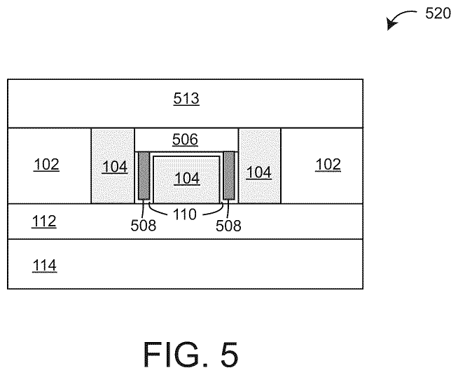

An anti-fuse may comprise an anti-fuse block that electrically separate at least two conductive features. An anti-fuse may electrically separate conductive features on a same substrate or conductive features on different substrates. For example, anti-fuse block 506 shown in FIG. 5 separates conductive features 508 on a same substrate 114. The anti-fuse blocks 106 in FIGS. 1A-1D may be used to separate conductive features on different substrates (e.g., conductive feature 108 on substrate 114 and conductive feature 308 on substrate 314 of FIG. 3).

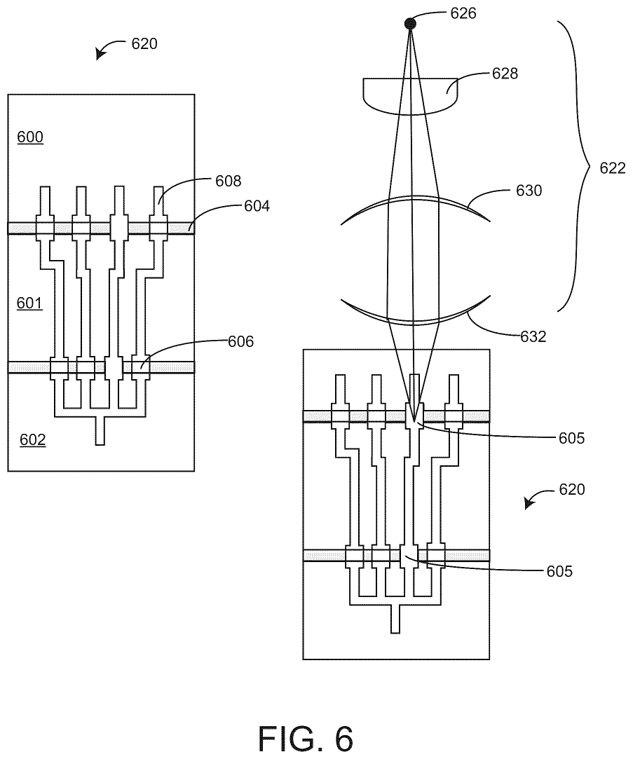

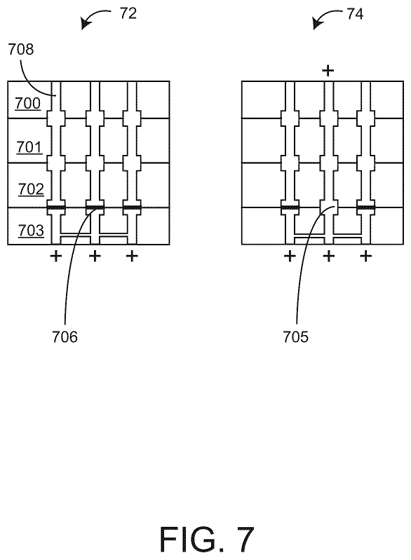

In some embodiments, an anti-fuse block may comprise only one layer. For example, an anti-fuse block 606 as shown in FIG. 6 has only one anti-fuse block 606 separating conductive features 608. In another example, an anti-fuse block 706 as shown in FIG. 7 has only one anti-fuse block 706 separating conductive features 708.

In some embodiments, an anti-fuse block may comprise more than one layer. For example, an anti-fuse block as shown in FIGS. 3A-3B may comprise a first layer or portion (e.g., anti-fuse block 106) and a second layer or portion (e.g., anti-fuse block 306).

Turning back to FIG. 1A, a top view of anti-fuse device 100 shows a first oxide layer 102, a second oxide layer 104, and anti-fuse blocks 106. The second oxide layer 104 is disposed in the first oxide layer 102, and the anti-fuse blocks 106 are disposed in the second oxide layer 104. FIGS. 1B-1D show cross-sectional views of one or more anti-fuse blocks 106, each disposed on a corresponding conductive feature 108 and a barrier layer 110. The barrier layer 110 separates the conductive features 108 and the second oxide layer 104. The first oxide layer 102, second oxide layer 104, conductive features 108, barrier layer 110, and anti-fuse blocks 106 are disposed on a dielectric layer 112 disposed on a substrate 114.

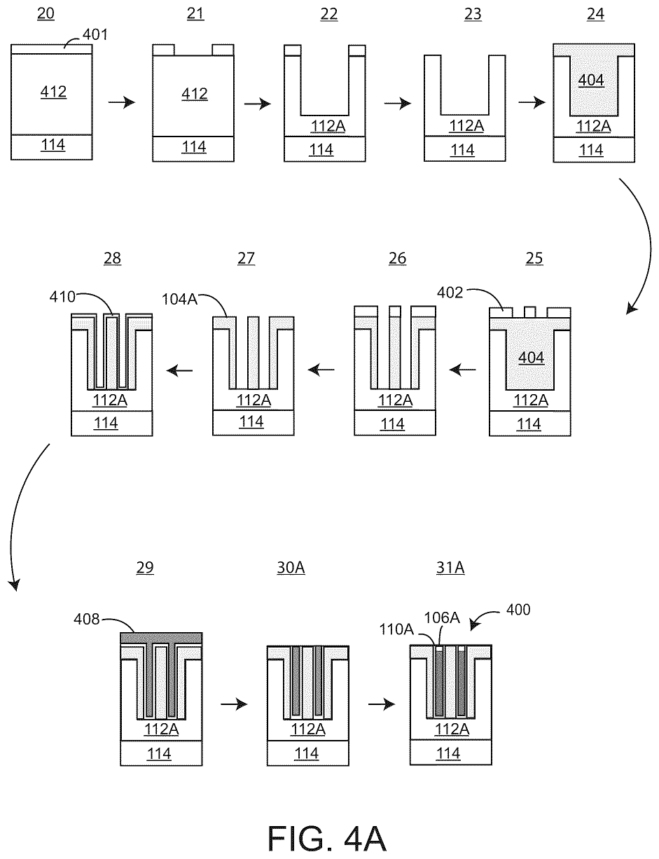

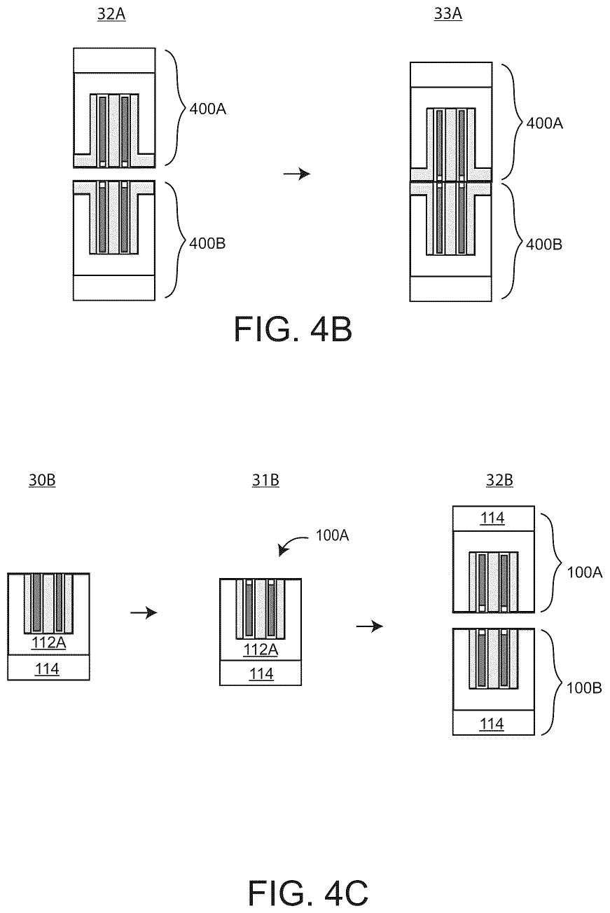

In some embodiments, a second oxide layer 104A covers a top surface of a first oxide layer 102. For example, the inset of FIG. 1B and the left inset of FIG. 1D show a second oxide layer 104A on top of first oxide layer 102. Details regarding forming such features are described in relation to FIG. 4A.

In some embodiments, a single patterned dielectric layer 112A may comprise the first oxide layer 102 and the dielectric layer 112. For example, the right inset of FIG. 1D shows a single patterned dielectric layer 112A. Details regarding forming such features are described in relation to FIG. 4A.

The first oxide layer 102 may comprise a silicon oxide material (e.g., SiO₂, thermal oxide, or a tetraethyl orthosilicate (TEOS) deposited oxide). In some embodiments, a dielectric layer may be used in place of the first oxide layer 102. The dielectric layer may comprise any suitable dielectric material, such as those mentioned in the present disclosure.

The second oxide layer 104 may comprise Silox material, or a type of silicon oxide material (e.g., SiO₂) which has hydrogen in its lattice. For example, silox may be silicon oxide deposited using silane and oxygen. Silox may be formed using a chemical vapor deposition (CVD), and/or a plasma-CVD process. The deposition conditions of Silox may determine the hydrogen content. For example, depositing Silox at a higher rate and lower temperature may increase the amount of hydrogen in the Silox.

The anti-fuse block 106 may be a copper oxide anti-fuse block and comprise a copper oxide material. Copper oxide may come in different phases. For example, copper oxide may be represented by the chemical formula CuₓO with 1≤x≤2 (e.g., Cu₂O, CuO) or Cu₄O₃. Different phases of copper oxide may have different crystallographic phases, band gaps, and other properties (e.g., resistivities). The anti-fuse block 106 may comprise copper oxide material of any suitable phase of copper oxide or mixture thereof as a material.

The hydrogen in the Silox material (e.g., of the second oxide layer 104) can be thermally activated to reduce the copper oxide material (e.g., of the anti-fuse block 106). Example chemical reactions leading to CuₓO reduction into Cu may be represented as follows: 2CuO+H₂→Cu₂O+H₂O; Cu₂O+H₂→Cu₂+H₂O.

The conductive feature 108 may comprise a copper material. The copper material may be electrochemically deposited copper (ECD Cu), or copper material formed using any suitable deposition technique (e.g., sputtered, evaporated, etc.).

The barrier layer 110 separates the conductive feature 108 from the second oxide layer 104. The barrier layer 110 may comprise tantalum (Ta) or tantalum nitride (TaN). In some embodiments, the barrier layer may comprise a single layer or multiple layers. The barrier layer 110 may be disposed between the conductive feature 108 and the dielectric layer 112. In some embodiments, the barrier layer 110 may not be disposed between the conductive feature 108 and the dielectric layer 112. For example, the barrier layer 110 may be on sidewall surfaces of a conductive feature 108, but not on a bottom surface of conductive feature 108.

The dielectric layer 112 may comprise any suitable dielectric material, such as those mentioned in the present disclosure. In some embodiments, the dielectric layer 112 comprises a silicon oxide material (e.g., SiO₂, thermal oxide, or a tetraethyl orthosilicate (TEOS) deposited oxide).

The substrate 114 may comprise a silicon material. The substrate 114 may be any suitable semiconductor substrate, such as those mentioned in the present disclosure.

In some embodiments, a barrier layer 110 may not separate the anti-fuse block 106 from the second oxide layer 104. For example, anti-fuse block 106 may be adjacent to second oxide layer 104 without an intervening barrier layer 110 as shown in FIGS. 1A-1D. In some embodiments, a barrier layer 110A may separate the anti-fuse block 106A from the second oxide layer 104A. For example, barrier layer 110A separates the anti-fuse block 106A form the second oxide layer 104A as shown in the inset of FIG. 1B.

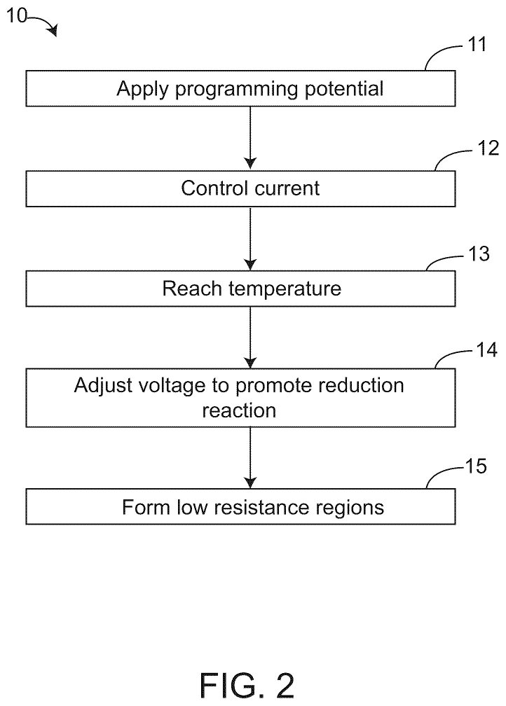

FIG. 2 is a flow diagram setting forth a method 10 of reducing an anti-fuse (e.g., anti-fuse block), according to some embodiments. Generally, the method includes reducing the resistive anti-fuse (e.g., copper oxide, CuₓO) to a conductive path (e.g., copper Cu) by passing a DC or an AC current through the anti-fuse/metal junction or across a resistor adjacent to the anti-fuse path.

At block 11, the method 10 includes applying a programming potential. The programming potential (e.g., voltage) may be applied to the anti-fuse/metal junction or across an adjacent resistor to obtain a current for local heating. The current may be alternating current (AC) or a direct current (DC). The current may be passed across the junction between conductive features 108 or 308, and anti-fuse blocks 106 or 306 of FIG. 3 to form precursor paths, respectively. As another example, a current may be passed across the junction between conductive features 508 and anti-fuse block 506 of FIG. 5 to form a precursor path.

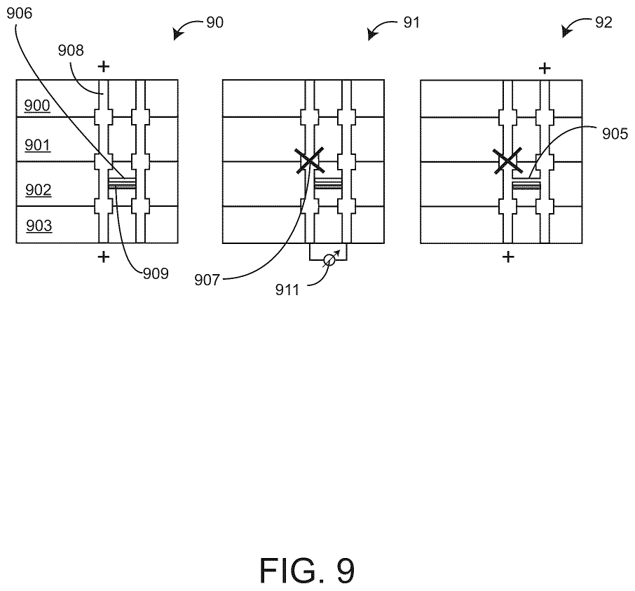

In some embodiments, a programming potential may be applied across a resistor in proximity to the anti-fuse block. For example, FIG. 9 shows resistor 909 adjacent to the anti-fuse block 906, and a current may be passed through the resistor 909, thereby heating the resistor 909. The heat from the resistor 909 heats up the nearby anti-fuse block 906 (e.g., copper oxide) and reduces the block 906, completely or partially, to a conductive path (e.g., Cu).

At block 12, the method 10 includes controlling the current (e.g., AC or DC) across a metal/anti-fuse junction, or across an adjacent resistor. The current may be controlled by applying a programmable potential. For example, the method 10 may include adjusting the programmable potential such that a particular temperature is reached at the path.

At block 13, the method 10 includes reaching a particular temperature at the junction or the adjacent resistor. For example, the particular temperature may be about (or more than about, or less than about) 250° C., 225° C., 200° C., 175° C., or 150° C. For example, the current may be set such that a temperature of 250° C. is not exceeded locally, as other features around the anti-fuse may become unstable beyond 250° C.

At block 14, the method 10 includes adjusting or controlling the programmable potential to promote the reduction reaction of the anti-fuse. In some embodiments, the potential may be increased until the anti-fuse block (e.g., completely or partially) is reduced to a corresponding metal. For example, copper oxide is reduced to metallic Cu as embodied by the equations: 2CuO+H₂→Cu₂O+H₂O; Cu₂O+H₂→Cu₂+H₂O

At block 15, the method 10 includes sufficiently reducing the anti-fuse to form a low resistance region with the desired conductivity. For example, in FIG. 3, the anti-fuse blocks 106 and/or 306 (e.g., copper oxide) are reduced, completely or partially, to metal (e.g., Cu), forming conducting path(s) across conductive features 108 and 308, respectively. For example, in FIG. 5, the anti-fuse block 506 (e.g., copper oxide) is reduced, completely or partially, to metal (e.g., Cu), forming a conducting path across conductive features 508. For example, in FIG. 9, anti-fuse block 906 (e.g., copper oxide) adjacent to resistor 909 (e.g., NiV), is reduced, completely or partially, to metal (e.g., Cu), forming a conducting path across conductive features 908.

For any of the blocks 11-15, the programmable potential may be less than about 12V, and the ramp time may be selected to model the resistance of the path.

FIGS. 3A-3B schematically illustrate cross-sectional views of example bonded semiconductor substrates (e.g., chips, devices) including bonded anti-fuse blocks, according to some embodiments. FIG. 3A shows a view of an anti-fuse device 100 (e.g., same view as shown in FIG. 1C) bonded to an anti-fuse device 300. FIG. 3B shows an anti-fuse device 100 (e.g., same view as shown in FIG. 1B) bonded to an anti-fuse portion 300. In some embodiments, the anti-fuse device 300 is similar to or the same as the anti-fuse device 100 shown in FIG. 1C. For example, the substrate 314, a dielectric layer 312, a barrier layer 310, a conductive feature 308, a first oxide layer 302, and second oxide layer 304 may be similar to substrate 114, dielectric layer 112, barrier layer 110, conductive feature 108, first oxide layer 102 and second oxide layer 104, respectively.

The anti-fuse devices 100 and 300 are bonded together such that the anti-fuse blocks 106 and 306 contact each other directly. For example, the anti-fuse devices 100 and 300 may be directly bonded to each other. Direct dielectric bonds may be formed between surfaces of the oxide layers 102 and 302, between surfaces of the oxide layers 104 and 304, and/or between anti-fuse blocks 106 and 306 (e.g., comprising Silox). In some embodiments, the bonded anti-fuse blocks 106 and 306 are reduced (e.g., by heating, annealing, introducing hydrogen from nearby Silox) to form a conductive path (e.g., Cu) between conductive features 108 and 308. In some embodiments, the bonded anti-fuse blocks 106 and 306 may be reduced using methods as shown in FIGS. 6 and 7 of the present disclosure.

FIGS. 4A-4B schematically illustrates a process flow setting forth an example method to form an anti-fuse block between two semiconductor substrates (e.g., chips, devices), according to some embodiments. The process flow includes cross-sectional views of the semiconductor substrates at different steps of the method, according to some embodiments.

At block 20, the method includes depositing a first photoresist layer 401 on a dielectric layer 412 on a substrate 114. The dielectric layer 412 may a silicon (e.g., SiO₂, thermal oxide, or a tetraethyl orthosilicate (TEOS) deposited oxide) or any suitable dielectric material, such as those mentioned in the present disclosure.

At block 21 the method includes patterning the first photoresist layer 401 to open windows in the photoresist layer 401 and to expose the dielectric layer 412 below the photoresist layer 401. Photolithography may be used for the patterning the photoresist (e.g., a pattern can be etched through selective exposure of a light sensitive polymer to ultraviolet light).

At block 22, the method includes etching the dielectric layer 412 in the exposed areas (e.g., areas where the first photoresist layer 401 has been removed) to form a patterned dielectric layer 112A. In some embodiments, etching the dielectric layer 412 may be performed using dry etching such as using reactive-ion etching or any suitable etching technique. Dry etching the dielectric layer 412 may form trenches or deep wells in the dielectric layer 412.

At block 23, the method includes removing (e.g., stripping) the first photoresist layer 401. Removal of the first photoresist layer 401 may be performed using a dry etch process (e.g., plasma ashing, oxygen-based plasma), using solvents to dissolve the photoresist, or a combination thereof.

At block 24, the method includes depositing an oxide layer 404. The oxide layer 404 may comprise Silox material. The oxide layer 404 may be deposited on the patterned dielectric layer 112A. The oxide layer 404 is deposited in the etched trenches, as well field surfaces of dielectric layer 112A on substrate 114.

At block 25, the method includes depositing a second photoresist layer 402 and patterning the second photoresist layer 402 to expose portions of the oxide layer 404. Photolithography may be used for the patterning the photoresist layer 402.

At block 26, the method includes etching the oxide layer 404 in the exposed areas (e.g., areas where the second photoresist layer 402 has been removed) to form trenches or deep wells. Etching the oxide layer 404 may be performed using dry etching or any suitable etching technique.

At block 27, the method includes removing (e.g., stripping) the second photoresist layer 402 from the top of the oxide layer 104A (e.g., second oxide layer 104A as shown in inset of FIGS. 1B and 1D). Removal of the second photoresist layer 402 may be performed using a dry etch process (e.g., plasma ashing, oxygen-based plasma), using solvents to dissolve the photoresist, or a combination thereof.

At block 28, the method includes depositing a barrier layer 410. The barrier layer 410 may be correspond to (e.g., be similar to or the same as) barrier layer 110. The method may further comprise depositing a seed layer (e.g., a Cu seed layer). The barrier layer 410 and/or the seed layer may be deposited on the patterned oxide layer 104A (e.g., on bottom and/or side surfaces of the trenches in the patterned oxide layer 104A, on a top surface of the patterned oxide layer 404).

At block 29, the method includes depositing a conductive layer 408. The conductive layer 408 may comprise any suitable conductive material. The conductive layer 408 may be electrochemically deposited copper. In some embodiments, the conductive material comprises copper material formed using any suitable deposition technique (e.g., sputtered, evaporated, etc.). The conductive layer 408 may be deposited to fill the trenches. An overburden of the conductive layer 408 may be deposited on top surfaces of the barrier layer 410.

At block 30A, the method includes removing an overburden of the conductive layer 408. The method may include using Chemical Mechanical Polishing (CMP) to remove an overburden of the conductive layer 408. Removing the overburden of the conductive layer 408 may form conductive features 108. The method may further comprise removing an overburden of the barrier layer 410. In some embodiments, the method may include further removing an overburden of the oxide layer 404, as shown in FIG. 4C.

At block 31A, the method includes forming a copper oxide anti-fuse block 106A through oxidation of top portion of the exposed conductive features. The stack formed at block 31A is hereinafter referred to as anti-fuse device 400. In some embodiments, the copper oxide anti-fuse block 106A is separated from the oxide layer 104A by the barrier layer 110A. In some embodiments, as shown in FIG. 1B, the barrier layer (e.g., barrier layer 110) may not separate the anti-fuse block (e.g., anti-fuse block 106) from the oxide layer (e.g., oxide layer 104).

At blocks 32A and 33A, the method includes bonding anti-fuse devices 400A and 400B. Anti-fuse devices 400A and 400B correspond to anti-fuse device 400 of block 31A and may comprise same or similar components. The anti-fuse blocks in the anti-fuse devices 400A and 400B are aligned and bonded directly with each other. In some embodiments, the contacted anti-fuse blocks are reduced (e.g., by heating, annealing, introducing hydrogen from nearby Silox) to form a conductive path (e.g., Cu) between the adjacent conductive features.

FIG. 4C schematically illustrates a process flow setting forth an example method to form an anti-fuse block between two semiconductor substrates (e.g., chips, devices), according to some embodiments. For example, the process flow of FIG. 4C may be used to form the bonded anti-fuse block 106 and 306 of FIGS. 3A and 3B between two semiconductor substrates 114 and 314. The process flow includes cross-sectional views of the substrates at different steps of the method, according to some embodiments.

In some embodiments, block 30B may be similar to block 30A of FIG. 4A, except the method further includes removing an overburden of the oxide layer 404. In some embodiments, the method uses CMP to remove the overburden of conductive layer 408, barrier layer 410, and oxide layer 404 (e.g., shown in block 29 of FIG. 4A).

At block 31A, the method includes forming a copper oxide anti-fuse block 106A through oxidation of top portion of the exposed conductive layer 408. The structure formed at block 31A is hereinafter referred to anti-fuse device 100A. In some embodiments, anti-fuse device 100A corresponds to (e.g., is similar to or the same as) anti-fuse device 100 as shown in FIGS. 1A-1D. In some embodiments, the method includes forming a copper oxide anti-fuse block 506 through oxidation of a top horizontal portion of a conductive layer 408 connecting two horizontal portions (e.g., in a view similar to that shown in FIG. 1C).

At block 32B, the method includes bonding anti-fuse devices to each other. For example, a first anti-fuse device 100A and a second anti-fuse device 100B may be bonded to one another. The second anti-fuse device 100B may be similar to or the same as the first anti-fuse device 100A shown in block 31B. The anti-fuse blocks in the anti-fuse devices 100A and 100B are aligned and bonded directly with each other. In some embodiments, the bonded anti-fuse blocks are reduced (e.g., by heating, annealing, introducing hydrogen from nearby Silox) to form a conductive path (e.g., Cu) between the adjacent conductive features.

FIG. 5 schematically illustrates an example anti-fuse device 520 within a semiconductor substrate (e.g., chip, device), according to some embodiments. The anti-fuse device 520 may be similar to the anti-fuse device 100 as shown in FIG. 1C, except a top horizontal portion of conductive feature 108 in FIG. 1C may be oxidized to form the anti-fuse block 506 disposed on conductive features 508 to electrically separate the conductive features 508, and a third oxide layer 513 is disposed on top of the anti-fuse block 506, first oxide layer 102, and second oxide layer 104. Any of the variations shown in the insets of FIG. 1 may be applied to the anti-fuse 520. In some embodiments, a barrier layer 110 may not separate the anti-fuse block 506 from the second oxide layer 104. For example, anti-fuse block 506 may be adjacent to second oxide layer 104 without an intervening barrier layer.

In some embodiments, the conductive features 508 is similar to conductive features 108, except the conductive features 508 may comprise only vertical portions of conductive features 108 and the vertical portions are electrically separated from each other with the anti-fuse block 506. The anti-fuse block 506 is similar to anti-fuse block 106, except the anti-fuse block 506 electrically separates vertical portions of conductive features 108 (e.g., there may be no horizontal portion of conductive feature 108 connecting the vertical portions of conductive feature 108). In some embodiments, the anti-fuse block 506 is reduced (e.g., by heating, annealing, introducing hydrogen from nearby Silox) to form a conductive path (e.g., Cu) within the substrate (e.g., chip).

FIG. 6 schematically illustrates cross-sectional views of example anti-fuses bonded between semiconductor substrates (e.g., chips, devices) and a method to use a Bessel Lens arrangement for reducing the anti-fuses, according to some embodiments. Block 620 shows a first chip 600 (e.g., substrate) bonded to a second chip 601 (e.g., substrate), which is further bonded to a substrate 602 (e.g., substrate, interposer or packaging substrate). Conductive features 608 are disposed in each of the chips 600, 601 and the substrate 602. The conductive features 608 are aligned to each other and connected by anti-fuse blocks 606. An oxide layer 604 (e.g., Silox) may be disposed around the anti-fuse blocks 606 (e.g, copper oxide).

In some embodiments, the oxide layer 604 is similar to oxide layer 104, conductive feature 608 is similar to conductive feature 108, and anti-fuse block 606 is similar to anti-fuse block 106. In some embodiments, the anti-fuse block 606 is reduced (e.g., by heating, annealing, introducing hydrogen from nearby Silox) to form a conductive path 605 (e.g., Cu) between conductive features 608 of different substrates (e.g., chips 600, 601, and/or substrate 602).

A Bessel lens assembly 622 including an IR laser 626, an axicon lens 628, a first focusing lens 630, and a second focusing lens 632. The focusing lenses may comprise spherical lenses (e.g., convex or concave), and the axicon lens may comprise a conical lens. Bessel lens assemblies may provide for high precision and efficiency due to a long depth of focus and small spot size. Bessel beams may be a type of light propagation that does not diffract.

In some embodiments, the Bessel lens assembly 622 is used to reduce the anti-fuse block 606 at a selected locations (e.g., conductive path 605 between chips 600 and 601, and between chips 601 and 602). The IR laser 626 emits a light beam that passes through the axicon lens 628 to form a Bessel beam. The focusing lenses 630 and 632 further concentrate the Bessel beam at a focal point (e.g., at about focal length distance from focusing lens 632). The selected location (e.g., an anti-fuse block 606 between chips 600 and 601) lies at the focal point of the Bessel beam from Bessel lens assembly 622. The light energy from the focused Bessel beam reduces the anti-fuse block 606 at the selected location to form a conductive path 605 (e.g., Cu) between the chips 600 and 601. The Bessel beam may cover an area in the scale of micrometers. A distance of the location the Bessel beam may focus may be about 1-5 cm away from lens 632.

FIG. 7 schematically illustrates cross-sectional views of example anti-fuses bonded between semiconductor substrates (e.g., chips) and a method to electrically connect the substrates (e.g., chips), according to some embodiments. At block 72, the method may provide for stacked bonded substrates. For example, chips 700, 701, 702, and 703 may be attached or bonded (e.g., hybrid bonded) to each other to form a stack. In some embodiments, the number of bonded chips may be any suitable number of chips (e.g., more or fewer than four chips). The stacked chips may have no active connection. The stacked chips at block 72 may not have a programmed connection.

Conductive features 708 are disposed in each of the chips 700, 701, 702, and 703, and aligned to each other and bonded. The bonded conductive features 708 form conductive paths between the chips 700, 701, and 702. In between the chips 702 and 703, the conductive features 708 are connected by anti-fuse blocks 706 (e.g., copper oxide) instead of being directly connected to each other. The anti-fuse blocks 706 electrically block or separate the conductive features 708 at these locations (e.g., between chips 702 and 703). In some embodiments, conductive features 708 is similar to conductive features 108, and anti-fuse block 706 is similar to anti-fuse block 106.

At block 74, the anti-fuse block 706 is reduced to form a conductive path 705 (e.g., Cu) between chips 702 and 703 at a specific location. The stacked chips at block 74 may have a programmed connection. The anti-fuse block 706 may be reduced using local thermal programming of CuₓO path to create a conductive path 705. In some embodiments, the conductive path may be formed by heating, annealing, using a Bessel lens assembly, introducing hydrogen from nearby Silox.

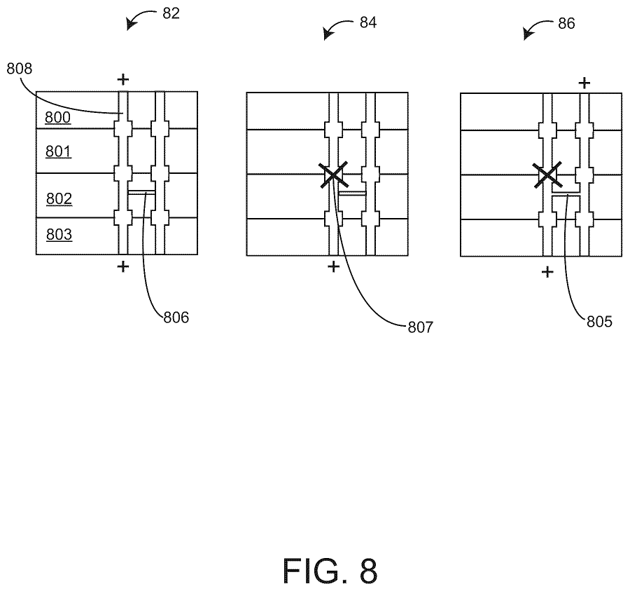

FIG. 8 schematically illustrates cross-sectional views of example anti-fuse disposed within a semiconductor substrate (e.g., chip) and a method to repair electrical connections between substrates (e.g., chips), according to some embodiments. At block 82, a method may include providing stacked substrates. For example, chips 800, 801, 802, and 803 may be attached or bonded to each other to form a stack. In some embodiments, the number of bonded chips may be any suitable number of chips (e.g., more or fewer than four chips). The stacked chips shown at block 82 may be a functioning part.

Conductive features 808 are disposed in each of the chips 800, 801, 802, and 803 may be aligned to each other and bonded to form conductive paths between the chips. Within chip 802, two conductive features 808 are connected by an insulating anti-fuse block 806 (e.g., copper oxide). The anti-fuse block 806 may electrically block or separate the conductive features 808 that it is connected to. The conductive features 808 may be similar to conductive feature 108, and anti-fuse block 806 may be similar to anti-fuse block 106.

At block 84, the method may comprise detecting a defective connection. For example, the method may comprise detecting that there is a defective connection at location 807. The connection at location 807 may be damaged or defective such that the conductive feature 808 at location 807 does not conduct current sufficiently. In some embodiments, the stacked chips shown at block 84 may be a part with a bad electrical connection. For example, the junction e.g., bonded pads connecting conductive features 808 between chips 801 and 802 at location 807 may not be electrically connected (e.g., no electrical connection may be between a conductive feature in chip 803 to a conductive feature in chip 800).

At block 86, the method may comprise reducing the anti-fuse block 806 to form a conductive path 805 (e.g., Cu) within chip 802. This newly formed conductive path 805 may compensate for the reduction in current through the stack of chips due to the damage at location 807. The stack of chips at block 86 may be repaired part. The method may include reducing the anti-fuse block 806 by local thermal programming of CuₓO path to create a conducting bypass. For example, an electrical connection may be between a conductive feature in chip 803 to a conductive feature in chip 800 through the conductive path 805. In some embodiments, the reduction of the anti-fuse block 806 may be done by heating, annealing, using a Bessel lens assembly, introducing hydrogen from nearby Silox.

FIG. 9 schematically illustrates cross-sectional views of example anti-fuses and corresponding resistors disposed within semiconductor substrates (e.g., chips) and a method to repair electrical connections between substrates (e.g., chips), according to some embodiments. At block 90, the method may provide chips 900, 901, 902, and 903 attached or bonded to each other to form a stack. In some embodiments, the number of bonded chips may be any suitable number of chips (e.g., more or fewer than four chips). The stacked chips may be a functioning part at block 90.

Conductive features 908 are disposed in each of the chips 900, 901, 902, and 903, and may be aligned and bonded to each other to form conductive paths between the chips. Within chip 902, two conductive features 908 are further connected by an insulating anti-fuse block 906 (e.g., copper oxide) and a resistor 909. The resistor 909 may be a built-in resistor comprising Nickel-Vanadium (NiV) or any suitable resistive material. The resistor 909 may be close in proximity to the anti-fuse block 906. In some embodiments, conductive feature 908 is similar to conductive feature 108, and anti-fuse block 906 is similar to anti-fuse block 106.

At block 91, the method may comprise detecting a defective connection. For example, a connection at location 907 may be damaged such that the conductive feature 908 at this location can no longer conduct current sufficiently. The stacked chips at block 91 may be a part with a bad electrical connection. The method may include applying AC/DC power to the resistor 909. An AC/DC power supply 911 may supply controllable current to resistor 909 to heat the resistor. In some embodiments, the method of FIG. 2 (e.g., blocks 11-14) may be applied to or correspond to block 91 of FIG. 9. In some embodiments, the resistor may have separate connections (e.g., separate traces not through conductive features 908 that connect it to AC/DC power supply 911).

At block 92, the anti-fuse block 906 is reduced by the heat from resistor 909 to form a conductive path 905 (e.g., Cu) within chip 902. This newly formed conductive path 905 may compensate for the reduction in current through the stack of chips due to the damage at location 907. In some embodiments, the method of FIG. 2 (e.g., block 15) may apply to or correspond to block 92 of FIG. 9.

It is contemplated that any combination of the methods described above may be used to form the copper oxide anti-fuse and subsequently reduce it to conductive Cu whether or not expressly recited herein.

In some embodiments, a silicon substrate may comprise a Si(001) surface.

In some embodiments, a thickness of the copper oxide anti-fuse block is about tens of nanometers (e.g., about or greater than about 10 nm, 20 nm, 30 nm, 40 nm, or 50 nm).

In some embodiments, resistive paths in manufactured dies, or die stacks may be later selectively programmed by in-situ chemical reduction of copper oxide into conductive metallic copper.

In some embodiments, copper oxide may be formed in any suitable way. For example, copper oxide may be formed by oxygen ashing of Cu pads (e.g., to form Cu₂O). Copper oxide may be formed by Cu thermal oxidation (e.g., at about 200-300° C.) in oxygen (O₂) atmosphere (e.g., to form CuO). Copper oxide may be formed by Cu sputter or plasma deposition using Cu target in O₂/He (e.g., to form CuₓO, 1≤x≤2). Copper oxide may be formed by CuO reactive sputtering or vacuum evaporation. Copper oxide may be formed by Successive Ionic Layer Adsorption and Reaction (SILAR). Copper oxide may be formed by electrochemical Cu oxidation and CuₓO deposition. In some embodiments, copper oxide may be separately on a small die and used ZiBond to be bonded to a chip.

In some embodiments, Silox SiO₂ deposition may be performed using hard masking. The deposition may be part of a back-end process.

In some embodiments, selected CuₓO anti-fuses may be programmed one by one (e.g., individually) in a first method. In some embodiments, the first method may include keeping or maintaining a die at ˜200° C. (e.g., about 200° C.) and applying additional local heating of selected pads using IR laser with Bessel lens assembly. In some embodiments, the first method may include rapid thermal anneal or RTA methods of thermal annealing with high rate and short time thermal pulses. In some embodiments, the first method may include adding a micro resistor below Cu—CuₓO junction to provide local heating (e.g., by passing a current through the micro resistor).

In some embodiments, selected CuₓO anti-fuses are programmed by electrical methods in a second method. In some embodiments, the second method includes, once initial Cu conducting path is created by annealing, programming a selected anti-fuse may include passing a small current through a junction to heat it locally to further the CuₓO (1≤x≤2) reduction and achieve a desired conductivity.

In some embodiments, a plurality or a large number of CuₓO anti-fuses may be programmed in a third method. In some embodiments, the third method includes, during a ZIBOND process and annealing (e.g., about 200-250° C.), CuₓO is subjected to high pressures from Cu expansion leading to O₂ migration from CuₓO into Cu grain boundaries (e.g., CTE 17 ppm/° C. (Cu), CTE 3 ppm/° C. (Cu₂O), CTE 5 ppm/° C. (CuO)). In some embodiments, the third method may include inducing a CuₓO reduction with H₂ from Silox SiO₂ and subsequent water diffusion into surrounding Silox SiO₂. In some embodiments, the third method may include annealing in forming gas (e.g., 5% H₂/95% He or any similar or suitable mixture) at about 200-250° C. may be used. In some embodiments, the third method may include hydrogen gas plasma reduction of CuₓO (1≤x≤2).

In some embodiments, a combination of the first to third methods may be used.

In some embodiments, a programmable apparatus performs CuₓO reduction into Cu in anti-fuse. A method and apparatus for CuₓO reduction may include or perform passing DC or AC current through CuₓO—Cu junction. Initiating a local conducting precursor path may be performed by using one of the programming methods (e.g., first, second, third method or any combination thereof). In some embodiments, local heating occurs when passing small current through CuₓO—Cu (with a precursor path). In some embodiments, programmable electric current may be kept low (e.g., not to exceed a temperature of about 250° C. locally). In some embodiments, programmable voltage may be less than or equal to about 12V and time ramp may be selected to model resistance of a junction.

In some embodiments, a method and apparatus for CuₓO reduction may include or perform passing DC/AC current through resistor adjacent to CuₓO path. In some embodiments, a built-in resistor may be used in a circuit to program CuₓO→Cu reduction reaction to obtain a local conducting CuₓO—Cu precursor path. In some embodiments, the method may include applying a programming potential, controlling a current, reaching a temperature, adjusting voltage to promote reduction reaction, and forming a low resistance region.

In some embodiments, a chip 2/chip 1/interposer stack may have one of the resistive paths activated by thermal reduction of CuₓO into Cu. For example, the whole stack may be at temperatures around 200° C. (e.g., at about 200° C., at about 200° C.-250° C.). In some embodiments, a CuₓO→Cu reduction in a selected pad may take place locally by applying IR Laser and Bessel Lens Assembly. The Bessel Lens Assembly may comprise a first lens (e.g., axicon lens, fluid axicon lens), a second lens, and a third lens. In some embodiments, the laser energy of Bessel beam will be concentrated at ˜focal length distance from the third lens. For example, the focal length distance from the third lens to the selected pad may be about 1-5 cm or any suitable distance.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 1008a and/or 1008b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

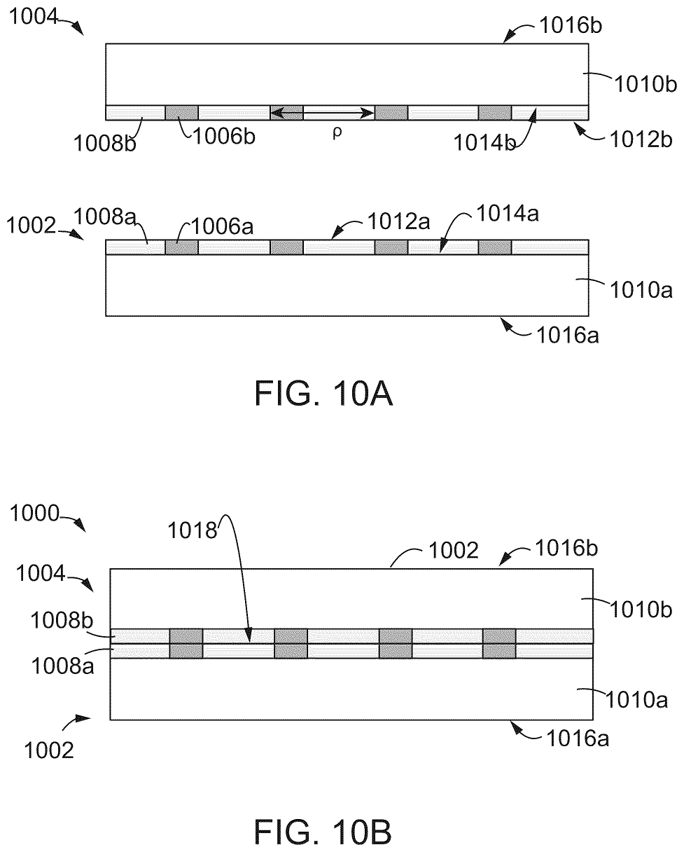

FIGS. 10A and 10B schematically illustrate cross-sectional side views of first and second elements 1002, 1004 prior to and after, respectively, a process for forming a directly bonded structure, and more particularly a hybrid bonded structure, according to some embodiments. In FIG. 10B, a bonded structure 1000 comprises the first and second elements 1002 and 1004 that are directly bonded to one another at a bond interface 1018 without an intervening adhesive. Conductive features 1006a of a first element 1002 may be electrically connected to corresponding conductive features 1006b of a second element 1004. In the illustrated hybrid bonded structure 1000, the conductive features 1006a are directly bonded to the corresponding conductive features 1006b without intervening solder or conductive adhesive.

The conductive features 1006a and 1006b of the illustrated embodiment are embedded in, and can be considered part of, a first bonding layer 1008a of the first element 1002 and a second bonding layer 1008b of the second element 1004, respectively. Field regions of the bonding layers 1008a, 1008b extend between and partially or fully surround the conductive features 1006a, 1006b. The bonding layers 1008a, 1008b can comprise layers of non-conductive materials suitable for direct bonding, as described above, and the field regions are directly bonded to one another without an adhesive. The non-conductive bonding layers 1008a, 1008b can be disposed on respective front sides 1014a, 1014b of base substrate portions 1010a, 1010b.

The first and second elements 1002, 1004 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 1002, 1004, and back-end-of-line (BEOL) interconnect layers over such semiconductor portions. The bonding layers 1008a, 1008b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1010a, 1010b, and can electrically communicate with at least some of the conductive features 1006a, 1006b. Active devices and/or circuitry can be disposed at or near the front sides 1014a, 1014b of the base substrate portions 1010a, 1010b, and/or at or near opposite backsides 1016a, 1016b of the base substrate portions 1010a, 1010b. In other embodiments, the base substrate portions 1010a, 1010b may not include active circuitry, but may instead comprise dummy substrates, passive interposers, passive optical elements (e.g., glass substrates, gratings, lenses), etc. The bonding layers 1008a, 1008b are shown as being provided on the front sides of the elements, but similar bonding layers can be additionally or alternatively provided on the back sides of the elements.

In some embodiments, the base substrate portions 1010a, 1010b can have significantly different coefficients of thermal expansion (CTEs), and bonding elements that include such different based substrate portions can form a heterogenous bonded structure. The CTE difference between the base substrate portions 1010a and 1010b, and particularly between bulk semiconductor (typically single crystal) portions of the base substrate portions 1010a, 1010b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 1010a, 1010b comprises a more conventional substrate material. For example, one of the base substrate portions 1010a, 1010b comprises lithium tantalate (LiTaO₃) or lithium niobate (LiNbO₃), and the other one of the base substrate portions 1010a, 1010b comprises silicon (Si), quartz, fused silica glass, sapphire, or a glass. In other embodiments, one of the base substrate portions 1010a, 1010b comprises a III-V single semiconductor material, such as gallium arsenide (GaAs) or gallium nitride (GaN), and the other one of the base substrate portions 1010a, 1010b can comprise a non-III-V semiconductor material, such as silicon (Si), or can comprise other materials with similar CTE, such as quartz, fused silica glass, sapphire, or a glass. In still other embodiments, one of the base substrate portions 1010a, 1010b comprises a semiconductor material and the other of the base substrate portions 1010a, 1010b comprises a packaging material, such as a glass, organic or ceramic substrate.

In some arrangements, the first element 1002 can comprise a singulated element, such as a singulated integrated device die. In other arrangements, the first element 1002 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 1004 can comprise a singulated element, such as a singulated integrated device die. In other arrangements, the second element 1004 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 1002, 1004 are shown, any suitable number of elements can be stacked in the bonded structure 1000. For example, a third element (not shown) can be stacked on the second element 1004, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 1002. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1008a, 1008b, the bonding layers 1008a, 1008b can be prepared for direct bonding. Non-conductive bonding surfaces 1012a, 1012b at the upper or exterior surfaces of the bonding layers 1008a, 1008b can be prepared for direct bonding by polishing, for example, by chemical mechanical polishing (CMP). The roughness of the polished bonding surfaces 1012a, 1012b can be less than 30 Å rms. For example, the roughness of the bonding surfaces 1012a and 1012b can be in a range of about 0.1 Å rms to 15 Å rms, 0.5 Å rms to 10 Å rms, or 1 Å rms to 5 Å rms. Polishing can also be tuned to leave the conductive features 1006a, 1006b recessed relative to the field regions of the bonding layers 1008a, 1008b.

Preparation for direct bonding can also include cleaning and exposing one or both of the bonding surfaces 1012a, 1012b to a plasma and/or etchants to activate at least one of the surfaces 1012a, 1012b. In some embodiments, one or both of the surfaces 1012a, 1012b can be terminated with a species after activation or during activation (e.g., during the plasma and/or etch processes). Without being limited by theory, in some embodiments, the activation process can be performed to break chemical bonds at the bonding surface(s) 1012a, 1012b, and the termination process can provide additional chemical species at the bonding surface(s) 1012a, 1012b that alters the chemical bond and/or improves the bonding energy during direct bonding. In some embodiments, the activation and termination are provided in the same step, e.g., a plasma to activate and terminate the surface(s) 1012a, 1012b. In other embodiments, one or both of the bonding surfaces 1012a, 1012b can be terminated in a separate treatment to provide the additional species for direct bonding. In various embodiments, the terminating species can comprise nitrogen. For example, in some embodiments, the bonding surface(s) 1012a, 1012b can be exposed to a nitrogen-containing plasma. Other terminating species can be suitable for improving bonding energy, depending upon the materials of the bonding surfaces 1012a, 1012b. Further, in some embodiments, the bonding surface(s) 1012a, 1012b can be exposed to fluorine. For example, there may be one or multiple fluorine concentration peaks at or near a bond interface 1018 between the first and second elements 1002, 1004. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1000, the bond interface 1018 between two non-conductive materials (e.g., the bonding layers 1008a, 1008b) can comprise a very smooth interface with higher nitrogen (or other terminating species) content and/or fluorine concentration peaks at the bond interface 1018. In some embodiments, the nitrogen and/or fluorine concentration peaks may be detected using various types of inspection techniques, such as SIMS techniques. The polished bonding surfaces 1012a and 1012b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1008a and 1008b can be directly bonded to one another without an adhesive. In some embodiments, the elements 1002, 1004 are brought together at room temperature, without the need for application of a voltage, and without the need for application of external pressure or force beyond that used to initiate contact between the two elements 1002, 1004. Contact alone can cause direct bonding between the non-conductive surfaces of the bonding layers 1008a, 1008b (e.g., covalent dielectric bonding). Subsequent annealing of the bonded structure 1000 can cause the conductive features 1006a, 1006b to directly bond.

In some embodiments, prior to direct bonding, the conductive features 1006a, 1006b are recessed relative to the surrounding field regions, such that a total gap between opposing contacts after dielectric bonding and prior to anneal is less than 15 nm, or less than 10 nm. Because the recess depths for the conductive features 1006a and 1006b can vary across each element, due to process variation, the noted gap can represent a maximum or an average gap between corresponding conductive features 1006a, 1006b of two joined elements (prior to anneal). Upon annealing, the conductive features 1006a and 1006b can expand and contact one another to form a metal-to-metal direct bond.

During annealing, the conductive features 1006a, 1006b (e.g., metallic material) can expand while the direct bonds between surrounding non-conductive materials of the bonding layers 1008a, 1008b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 1006a, 1006b can comprise discrete pads, contacts, electrodes, or traces at least partially embedded in the non-conductive field regions of the bonding layers 1008a, 1008b. In some embodiments, the conductive features 1006a, 1006b can comprise exposed contact surfaces of TSVs (e.g., through silicon vias).

As noted above, in some embodiments, in the elements 1002, 1004 of FIG. 10A prior to direct bonding, portions of the respective conductive features 1006a and 1006b can be recessed below the non-conductive bonding surfaces 1012a and 1012b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1006a, 1006b or to average depths of the recesses relative to local non-conductive field regions. Even for an individual conductive feature 1006a, 1006b, the vertical recess can vary across the feature, and so can be measured at or near the lateral middle or center of the cavity in which a given conductive feature 1006a, 1006b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 1006a, 1006b across the direct bond interface 1018 (e.g., small or fine pitches for regular arrays).

In some embodiments, a pitch p of the conductive features 1006a, 1006b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 1006a and 1006b to one of the lateral dimensions (e.g., a diameter) of the bonding pad is less than is less than 20, or less than 10, or less than 5, or less than 3 and sometimes desirably less than 2. In various embodiments, the conductive features 1006a and 1006b and/or traces can comprise copper or copper alloys, although other metals may be suitable, such as nickel, aluminum, or alloys thereof. The conductive features disclosed herein, such as the conductive features 1006a and 1006b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1002, 1004, as shown, the orientations of one or more conductive features 1006a, 1006b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1006b in the bonding layer 1008b (and/or at least one internal conductive feature, such as a BEOL feature) of the upper element 1004 may be tapered or narrowed upwardly, away from the bonding surface 1012b. By way of contrast, at least one conductive feature 1006a in the bonding layer 1008a (and/or at least one internal conductive feature, such as a BEOL feature) of the lower element 1002 may be tapered or narrowed downwardly, away from the bonding surface 1012a. Similarly, any bonding layers (not shown) on the backsides 1016a, 1016b of the elements 1002, 1004 may taper or narrow away from the backsides, with an opposite taper orientation relative to front side conductive features 1006a, 1006b of the same element.

As described above, in an anneal phase of hybrid bonding, the conductive features 1006a, 1006b can expand and contact one another to form a metal-to-metal direct bond. In some embodiments, the materials of the conductive features 1006a, 1006b of opposite elements 1002, 1004 can interdiffuse during the annealing process. In some embodiments, metal grains grow into each other across the bond interface 1018. In some embodiments, the metal is or includes copper, which can have grains oriented along the 1011 crystal plane for improved copper diffusion across the bond interface 1018. In some embodiments, the conductive features 1006a and 1006b may include nanotwinned copper grain structure, which can aid in merging the conductive features during anneal. There is substantially no gap between the non-conductive bonding layers 1008a and 1008b at or near the bonded conductive features 1006a and 1006b. In some embodiments, a barrier layer may be provided under and/or laterally surrounding the conductive features 1006a and 1006b (e.g., which may include copper). In other embodiments, however, there may be no barrier layer under the conductive features 1006a and 1006b.

It is contemplated that any combination of the methods described above may be used to form the anti-fuses, whether or not expressly recited herein.

The embodiments discussed above are intended to be illustrative and not limiting. One skilled in the art would appreciate that individual aspects of the antifuses and methods discussed herein may be omitted, modified, combined, and/or rearranged without departing from the scope of the disclosure.

1. A method comprising:
forming a plurality of anti-fuses, each comprising a copper oxide anti-fuse block that electrically separates at least two conductive copper features; and
reducing the copper oxide of one or more copper oxide anti-fuse blocks to form a conductive path between respective conductive copper features.

2. The method of claim 1, wherein forming the copper oxide anti-fuse blocks comprises exposing the conductive copper features to an oxygen based plasma.

3. The method of claim 1, wherein forming the copper oxide anti-fuse blocks comprises thermally oxidizing exposed surfaces of the conductive copper features.

4. The method of claim 1, wherein forming the copper oxide anti-fuse blocks comprises physical vapor deposition of copper in the presence of oxygen.

5. The method of claim 1, wherein forming the copper oxide anti-fuse blocks comprises physical vapor deposition of copper oxide by reactive sputtering from a copper oxide target.

6. The method of claim 1, wherein the copper oxide anti-fuse blocks are formed using a successive ionic layer adsorption and reaction process.

7. The method of claim 1, wherein the copper oxide anti-fuse blocks are formed using an electrochemical oxidation process.

8. The method of claim 1, wherein reducing the copper oxide comprises:
heating and maintaining a semiconductor device comprising the plurality of anti-fuses at greater than about 150° C.; and
using a laser to selectively heat the one or more copper oxide anti-fuse blocks.

9. The method of claim 1, wherein the copper oxide is reduced using a pulsed thermal anneal process.

10. The method of claim 1, wherein reducing the copper oxide comprises heating the one or more copper oxide anti-fuse blocks by flowing a current through one or more resistors disposed proximate to the copper oxide anti-fuse blocks.

11. The method of claim 8, wherein reducing the copper oxide further comprises locally heating the one or more copper oxide anti-fuse blocks by flowing a current through the copper to copper oxide junctions thereof.

12. The method of claim 1, wherein:
the copper oxide anti-fuse block and the conductive copper features are disposed in a first oxide layer;
the first oxide layer has a higher hydrogen content than a surrounding second oxide layer; and
reducing the copper oxide comprises reacting the copper oxide with hydrogen in the first oxide layer.

13. The method of claim 12, wherein the first oxide layer is formed using silane.

14. The method of claim 1, wherein reducing the copper oxide to copper comprises annealing in forming gas at about 200° C. to about 250° C.

15. The method of claim 1, wherein reducing the copper oxide to copper comprises hydrogen gas plasma reduction of copper oxide.

16. (canceled)

17. The method of claim 1, wherein:
the at least two conductive copper features comprise a first conductive feature and a second conductive feature; and
the first conductive feature and the second conductive feature are disposed in a same substrate.

18. The method of claim 1, wherein:
the at least two conductive copper features comprise a first conductive feature and a second conductive feature;
the first conductive feature is disposed in a first substrate; and
the second conductive feature is disposed in a second substrate.

19. The method of claim 18, further comprising:
contacting the first substrate to the second substrate to form a workpiece; and
heating the workpiece to about 150° C. or more, wherein heating the workpiece reduces the copper oxide of the one or more copper oxide anti-fuse blocks.

20. A semiconductor device comprising:
a plurality of anti-fuses, each comprising a copper oxide anti-fuse block that electrically separates at least two conductive copper features, wherein one or more copper oxide anti-fuse blocks is reduced to form a conductive path between respective conductive copper features.

21-23. (canceled)

24. The semiconductor device of claim 20, further comprising a first substrate and a second substrate, wherein:
the at least two conductive copper features comprise a first conductive feature and a second conductive feature;
the first conductive feature is disposed in the first substrate;
the second conductive feature is disposed in the second substrate; and
the first substrate is directly bonded to the second substrate.

25. (canceled)
